(19) United States
(12) Patent Application Publication
(10) Pub. No.: US 2006/0292708 A1
(43) Pub. Date: Dec. 28, 2006

(54) Circuit arrangement, redox recycling sensor, sensor assembly and a method for processing a current signal provided by a sensor electrode

(76) Inventors: Alexander Frey, Taufkirchen (DE); Christian Paulus, Weilhelm (DE); Roland Thewes, Grobenzell (DE)

Correspondence Address: BRINKS HOFER GILSON & LIONE;INFINEON, PO BOX 10395, CHICAGO, IL, 60610, US

(21) Appl. No.: 10/503,275

(22) PCT Filed: Jan. 17, 2003
(86) PCT No.: PCT/DE03/00122

§ 371 Date: Dec. 12, 2005

(30) Foreign Application Priority Data
Feb. 1, 2002 (DE) 102 03 996.8

(51) Int. Cl. H01L 21/00

(52) U.S. Cl. 438/10

(57) ABSTRACT

A circuit arrangement has a sensor electrode, a control circuit which is coupled to the sensor electrode via an input, and a current source which is coupled via a control input to a control output of the control circuit. The current source can be controlled by the control circuit. The control circuit is arranged so that if the current signal at its input is outside a predetermined current intensity range, the control circuit controls the current source so that the current source sets the electric current generated by it so that the electric current flowing into the input of the control circuit is brought to a predetermined current intensity value. Furthermore, the control circuit is set up in such a way that if the current signal at its input is within the predetermined current intensity range, the control circuit controls the current source so that the current source holds the electric current generated by it at the present value. Furthermore, the circuit arrangement has a detection unit which can detect the event that the current signal flowing into the control circuit via its input is outside the predetermined current intensity range.

The invention relates to a circuit arrangement, a redox recycling sensor, a sensor arrangement and a method for processing a current signal provided via a sensor electrode.

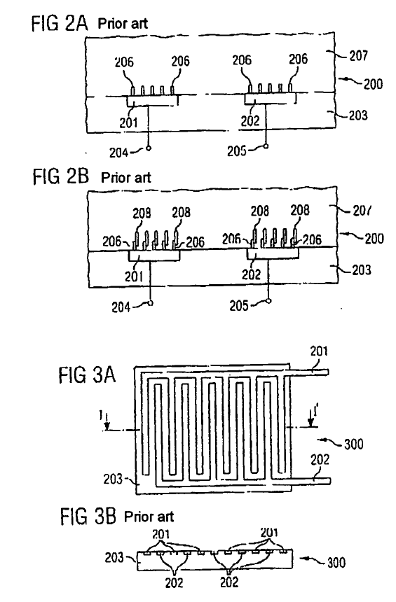

FIG. 2A and FIG. 2B show a biosensor chip, as described in [1]. The sensor 200 has two electrodes 201, 202 made of gold, which are embedded in an insulator layer 203 made of electrically insulating material. Connected to the electrodes 201, 202 are electrode terminals 204, 205, by means of which the electronic potential present at the electrode 201, 202 can be supplied. The electrodes 201, 202 are configured as planar electrodes. DNA probe molecules 206 (also referred to as capture molecules) are immobilized on each electrode 201, 203 (cf. FIG. 2A). The immobilization is effected in accordance with the gold-sulfur coupling. The analyte to be investigated, for example an electrolyte 207, is applied on the electrodes 201, 202.

If the electrolyte 207 contains DNA strands 208 with a base sequence which is complementary to the sequence of the DNA probe molecules 206, i.e. which sterically match the capture molecules in accordance with the key/lock principle, then these DNA strands 208 hybridize with the DNA probe molecules 206 (cf. FIG. 2B).

Hybridization of a DNA probe molecule 206 and a DNA strand 208 takes place only when the sequences of the respective DNA probe molecule and of the corresponding DNA strand 208 are complementary to one another. If this is not the case, then no hybridization takes place. Thus, a DNA probe molecule having a predetermined sequence is in each case only capable of binding a specific DNA strand, namely the one with a respectively complementary sequence, i.e. of hybridizing with it, which results in the high degree of selectivity of the sensor 200.

If hybridization takes place, then the value of the impedance between the electrodes 201 and 202 changes, as can be seen from FIG. 2B. This changed impedance is detected by applying a suitable electrical voltage to the electrode terminals 204, 205 and by registering the current resulting from this.

In the case of hybridization, the capacitive component of the impedance between the electrodes 201, 202 decreases. This can be attributed to the fact that both the DNA probe molecules 206 and the DNA strands 208, which possibly hybridize with the DNA probe molecules 206, are electrically nonconductive and thus, as can be seen, in part electrically shield the respective electrode 201, 202.

In order to improve the measurement accuracy, it is known from [2] to use a plurality of electrode pairs 201, 202 and to arrange the latter in parallel with one another, these being arranged intermeshed with one another, as can be seen, so that the result is a so-called interdigital electrode 300, FIG. 3A showing the plan view thereof and FIG. 3B showing the cross-sectional view thereof along the section line I-I′ from FIG. 3A. The dimensioning of the electrodes and the distances between the electrodes are of the order of magnitude of the length of the molecules to be detected, i.e. the DNA strands 208, or less, for example in the region of 200 nm or less.

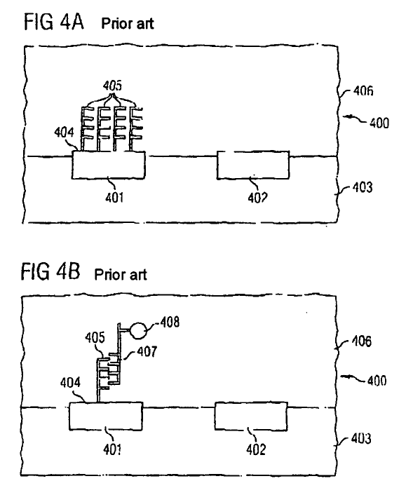

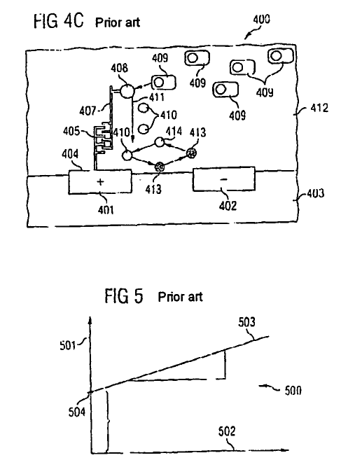

Furthermore, principles relating to a reduction/oxidation recycling process for registering macromolecular biomolecules are known for example from [1], [3]. The reduction/oxidation recycling process, also referred to hereinafter as the redox recycling process, will be explained in more detail below with reference to FIG. 4A, FIG. 4B, FIG. 4C.

FIG. 4A shows a biosensor 400 having a first electrode 401 and a second electrode 402, which are applied on an insulator layer 403. A holding region 404 is applied on the first electrode 401 made of gold. The holding region 404 serves for immobilizing DNA probe molecules 405 on the first electrode 401. Such a holding region is not provided on the second electrode 402.

If DNA strands 407 having a sequence which is complementary to the sequence of the immobilized DNA probe molecules 405 are intended to be registered by means of the biosensor 400, then the sensor 400 is brought into contact with a solution to be investigated, for example an electrolyte 406, in such a way that DNA strands 407 possibly contained in the solution 406 to be investigated can hybridize with the complementary sequence to the sequence of the DNA probe molecules 405.

FIG. 4B shows the case where the DNA strands 407 to be registered are contained in the solution 406 to be investigated and have hybridized with the DNA probe molecules 405.

The DNA strands 407 in the solution to be investigated are marked with an enzyme 408, with which it is possible to cleave molecules described below into electrically charged partial molecules. It is customary to provide a considerably larger number of DNA probe molecules 405 than there are DNA strands 407 to be determined contained in the solution 406 to be investigated.

After the DNA strands 407 possibly contained in the solution 406 to be investigated, together with the enzyme 408, are hybridized with the immobilized DNA probe molecules 405, the biosensor 400 is rinsed, as a result of which the nonhybridized DNA strands are removed and the biosensor chip 400 is cleaned of the solution 406 to be investigated. The rinsing solution used for rinsing or a further solution supplied separately in a further phase has an electrically uncharged substance added to it, which contains molecules that can be cleaved by means of the enzyme 408 at the hybridized DNA strands 407, into a first partial molecule 410 having a negative electrical charge and into a second molecule having a positive electrical charge.

As shown in FIG. 4C, the negatively charged first partial molecules 410 are attracted to the positively charged first electrode 401, which is indicated by means of the arrow 411 in FIG. 4C. The negatively charged first partial molecules 410 are oxidized at the electrode 401, which has a positive electrical potential, and are attracted as oxidized partial molecules 413 to the negatively charged second electrode 402, where they are reduced again. The reduced partial molecules 414 again migrate to the positively charged first electrode 401. In this way, an electric circulating current is generated, which is proportional to the number of charge carriers respectively generated by means of the enzymes 406.

The electrical parameter which is evaluated in this method is the change in the electric current m=dI/dt as a function of the time t, as is illustrated schematically in the diagram 500 in FIG. 5.

FIG. 5 shows the function of the electric current 501 depending on the time 502. The resulting curve profile 503 has an offset current I_{offset} 504, which is independent of the temporal profile. The offset current I_{offset} 504 is generated on account of non-idealities of the biosensor 400. An essential cause of the offset current I_{offset} resides in the fact that the covering of the first electrode 401 with the DNA probe molecules 405 is not effected in an ideal manner, i.e. not completely densely. In the case of a completely dense coverage of the first electrode 401 with the DNA probe molecules 405, an essentially capacitive electrical coupling would result on account of the so-called double-layer capacitance, which is produced by the immobilized DNA probe molecules 405, between the first electrode 401 and the electrically conductive solution 406 to be investigated. However, the incomplete coverage leads to parasitic current paths between the first electrode 401 and the solution 406 to be investigated, which inter alia also have resistive components.

However, in order to enable the oxidation/reduction process, the coverage of the first electrode 401 with the DNA probe molecules 405 is intended not to be complete at all, in order that the electrically charged partial molecules, i.e. the negatively charged first partial molecules 410, can pass to the first electrode 401 on account of an electrical force. In order, on the other hand, to achieve the greatest possible sensitivity of such a biosensor, and in order simultaneously to achieve the least possible parasitic effects, the coverage of the first electrode 401 with DNA probe molecules 405 should be sufficiently dense. In order to achieve a high reproducibility of the measured values determined by means of such a biosensor 400, both electrodes 401, 402 are intended always to provide an adequately large area afforded for the oxidation/reduction process in the context of the redox recycling process.

Macromolecular biomolecules are to be understood for example as proteins or peptides or else DNA strands having a respectively predetermined sequence. If proteins or peptides are intended to be registered as macromolecular biomolecules, then the first molecules and the second molecules are ligands, for example active substances with a possible binding activity, which bind the proteins or peptides to be registered to the respective electrode on which the corresponding ligands are arranged.

Examples of ligands that may be used are enzyme agonists, pharmaceuticals, sugars or antibodies or some other molecule which has the capability of specifically binding proteins or peptides.

If the macromolecular biomolecules used are DNA strands having a predetermined sequence which are intended to be registered by means of the biosensor, then it is possible, by means of the biosensor, for DNA strands having a predetermined sequence to be hybridized with DNA probe molecules having the sequence that is complementary to the sequence of the DNA strands as molecules on the first electrode.

A probe molecule (also called capture molecule) is to be understood as a ligand or a DNA probe molecule.

The value m=dI/dt introduced above, which corresponds to the gradient of the straight line 503 from FIG. 5, is proportional to the electrode area of the electrodes used for registering the measurement current. Therefore, the value m is proportional to the longitudinal extent of the electrodes used, for example in the case of the first electrode 201 and the second electrode 202 proportional to the length thereof perpendicular to the plane of the drawing in FIG. 2A and FIG. 2B. If a plurality of electrodes are connected in parallel, for example in the known interdigital electrode arrangement (cf. FIG. 3A, FIG. 3B), then the change in the measurement current is proportional to the number of electrodes respectively connected in parallel.

However, the value of the change in the measurement current may have a range of values that fluctuates to a very great extent, on account of various influences, the current range that can be detected by a sensor being referred to as the dynamic range. A current intensity range of five decades is often mentioned as a desirable dynamic range. Causes of the great fluctuations may be, in addition to the sensor geometry, also biochemical boundary conditions. Thus, it is possible that macromolecular biomolecules of different types to be registered will bring about greatly different ranges of values for the resulting measurement signal, i.e. in particular the measurement current and the temporal change thereof, which in turn leads to a widening of the required overall dynamic range with corresponding requirements for a predetermined electrode configuration with downstream uniform measurement electronics.

The requirements made of the large dynamic range of such a circuit have the effect that the measurement electronics are expensive and complicated in their configuration, in order to operate sufficiently accurately and reliably in the required dynamic range.

Furthermore, the offset current I_{offset} is often much greater than the temporal change in the measurement current m over the entire measurement duration. In such a scenario, it is necessary, within a large signal, to measure a very small time-dependent change with high accuracy. This makes very high requirements of the measurement instruments used, which makes the registering of the measurement current complex, complicated and expensive. This fact is also at odds with a miniaturization of sensor arrangements that is striven for.

To summarize, the requirements made of the dynamic range and therefore of the quality of a circuit for detecting sensor events are extremely high.

It is known, during circuit design, to take account of the non-idealities of the components used (noise, parameter variations) in the form such that an operating point at which these non-idealities play a part that is as negligible as possible is chosen for these components in the circuit.

If a circuit is intended to be operated over a large dynamic range, maintaining an optimum operating point over all the ranges becomes increasingly more difficult, more complex and thus more expensive, however.

Small signal currents that are obtained at a sensor, for example, can be raised with the aid of amplifier circuits to a level that permits the signal current to be forwarded for example to an external device or internal quantification.

A digital interface between the sensor and the evaluating system is advantageous for reasons of interference immunity and user-friendliness. Thus, the analog measurement currents are intended to be converted into digital signals actually in the vicinity of the sensor, which can be effected by means of an integrated analog-to-digital converter (ADC). Such an integrated concept for digitizing an analog small current signal is described in [4], for example.

In order to achieve the required dynamic range, the ADC should have a correspondingly high resolution and a sufficiently high signal-to-noise ratio. Integrating such an analog-to-digital converter in direct proximity to a sensor electrode furthermore constitutes a high technological challenge, and the corresponding process implementation is complex and expensive. Furthermore, achieving a sufficiently high signal-to-noise ratio in the sensor is extremely difficult.

The invention is based on the problem of providing an error-robust circuit arrangement with an improved detection sensitivity for electric currents that are very weakly variable with respect to time.

The problem is solved by means of a circuit arrangement, a redox recycling sensor, a sensor arrangement and a method for processing a current signal provided via a sensor electrode having the features in accordance with the independent patent claims.

The invention provides a circuit arrangement having a sensor electrode, a control circuit, which is coupled to the sensor electrode via an input, and a current source, which is coupled via its control input to a control output of the control circuit in such a way that the current source can be controlled by the control circuit, and which is coupled to the sensor electrode via its output. The control circuit is set up in such a way that if the current signal flowing into the control circuit via its input is outside a predetermined current intensity range, the control circuit controls the current source in such a way that the current source sets the electric current generated by it in such a way that the electric current flowing into the input of the control circuit is brought to a predetermined current intensity value. Furthermore, the control circuit is set up in such a way that if the current signal flowing into the control circuit via its input is within the predetermined current intensity range, the control circuit controls the current source in such a way that the current source holds the electric current generated by it at the present value. Furthermore, the circuit arrangement has a detection unit which can detect the event that the current signal flowing into the control circuit via its input is outside the predetermined current intensity range.

Clearly, a sensor event takes place at the sensor electrode, e.g. the hybridization of a DNA strand with an enzyme label at a capture molecule immobilized on the sensor electrode, the enzyme generating free charge carriers that bring about a current flow at the sensor electrode when a correspondingly suitable liquid is added. This brings about a time-dependent change in the sensor current at the sensor electrode, as shown for example in FIG. 5. This sensor current I_{Sensor} characteristically influences the current I_{Meas} flowing via the input of the control circuit. The control circuit is set up in such a way that if the current I_{Meas} flowing via its input is outside the predetermined current intensity range, the control circuit, via its control output, provides the control input of the current source with a signal such that the current source provides, at its output, a current value I_{Range} such that the current intensity I_{Meas} flowing via the input of the control circuit is brought to the predetermined current intensity value. A detection unit, which is preferably coupled to the control circuit, detects the event that the current signal I_{Meas} flowing into the control circuit via its input is outside the predetermined current intensity range. If by contrast, the current signal flowing into the control circuit via its input lies within the predetermined current intensity range, then the control circuit generates, at its control output, a corresponding signal that is provided to the control input of the current source and causes the latter to hold the current I_{Range} generated by it at the present, constant value. Clearly, a detection signal is generated upon each further rise in the sensor current I_{Sensor} by a predetermined current interval, so that a sensor event of a sensor electrode is registered in this way.

In other words, the signal processing of very small currents in the pA-nA range is realized according to the invention, the analog current signal I_{Sensor} being converted into a sequence of detection signals, for example pulses, in direct proximity to the sensor. In other words, a digitization is effected by means of the analog current signal I_{Sensor} being converted into a temporal sequence of detection signals, preferably into a frequency. On account of the signal processing in direct proximity to the sensor, disturbing influences on the path of the sensor signal to a signal processing unit are avoided or kept down, which results in a high signal-to-noise ratio. In other words, the useful signal is filtered out from the sensor signal in direct proximity to the sensor.

Furthermore, it is advantageous that, by means of the circuit arrangement according to the invention, the sensitivity and the dynamic range of the sensor or the signal processing unit can be set flexibly to the requirements of the individual case. As shown in FIG. 5, for example in the case of detecting DNA strands using the redox recycling principle, the hybridization events are converted into a signal current that rises in constant fashion with respect to time. The sensitivity and dynamic range can be adjusted by setting the measurement time and by setting the predetermined current intensity range which, when respectively exceeded, respectively triggers a detection pulse. A desired dynamic span of five decades (for example for registering electric currents of between 1 pA and 100 nA) can therefore be realized very simply according to the invention.

In accordance with an advantageous development of the circuit arrangement according to the invention, said circuit arrangement furthermore has a counter element, which is electrically coupled to the detection unit and which is set up in such a way that it counts the number and/or the temporal sequence of the events detected by the detection unit.

Preferably, the counter element is set up in such a way that if the electric current flowing into the input of the control circuit exceeds an upper limit of the predetermined current intensity range, the counter reading is increased by a predetermined value. By contrast, if the electric current flowing into the input of the control circuit falls below a lower limit of the predetermined current intensity range, the counter reading is preferably decreased by a predetermined value.

The described functionality of the counter element corresponds to the scenario where the sensor current has a sign such that it is progressively increased on account of a sensor event of the sensor current I_{Sensor}. Each time the predetermined current intensity range is exceeded, the counter reading is clearly increased by a predetermined value (preferably by “1”), whereas each time the predetermined range is undershot, the counter reading is decreased by a predetermined value (preferably by “1”).

In the case of a scenario that is complementary thereto, in which the sensor current has a sign such that the current I_{Sensor} is progressively decreased on account of a sensor event, the counter element is set up in such a way that if the electric current flowing into the input of the control circuit exceeds an upper limit of the predetermined current intensity range, the counter reading is decreased by a predetermined value, and that if the electric current flowing into the input of the control circuit falls below a lower limit of the predetermined current intensity range, the counter reading is increased by a predetermined value.

The lowering of the current value in a scenario in which a detection event increases the current value of a sensor electrode can be attributed for example to interfering and parasitic events, such as noise events, etc.

It is advantageous that, according to the invention, the detector selectively detects the situation of the predetermined current intensity range being exceeded or undershot and consequently either increments or decrements the counter reading of the counter element.

In other words, the signal is automatically averaged and errors on account of noise effects, etc. are thereby compensated for. This leads to an increase in the detection sensitivity.

Preferably, the current source is a voltage-controlled current source.

Furthermore, the control circuit preferably has, at its input, a current-voltage converter set up in such a way that the current present at the input of the control circuit is converted into an electrical voltage signal by means of the current-voltage converter.

In accordance with an advantageous development of the circuit arrangement according to the invention, said circuit arrangement is designed as an integrated circuit.

The integration of the circuit arrangement, for example into a silicon substrate (e.g. a chip in a wafer), brings about a high detection accuracy on account of the current signal processing on-chip. The current is processed on the chip directly and in direct proximity to the sensor electrode, thereby avoiding disturbing signals such as an additional noise on account of an increased communication path. Furthermore, it is advantageous that the dimensioning of the circuit arrangement can be reduced on account of the integration of the circuit arrangement according to the invention, for example into a semiconductor substrate. This miniaturization leads to a cost advantage since microscopic measurement equipment is obviated.

It must be emphasized that, on account of the integration of the circuit arrangement according to the invention into a semiconductor substrate the circuit arrangement can be produced using processes of semiconductor technology that are standardized and widespread, as well as being mature, which brings about quality and cost advantages.

Furthermore, the invention provides a redox recycling sensor having a circuit arrangement having the features described above.

The sensitivity of the circuit arrangement according to the invention is sufficiently high, as described, to be able to register very small electric currents such as usually arise during the detection of biomolecules of low concentration. Therefore, the circuit arrangement of the invention is preferably designed as a redox recycling sensor having the features described above with reference to FIG. 4A, FIG. 4B, FIG. 4C.

Moreover, the invention provides a sensor arrangement having a plurality of circuit arrangements having the features described. In particular, each of the circuit arrangements of the sensor arrangements may be designed as a redox recycling sensor.

Arranging a plurality of circuit arrangements for forming a sensor arrangement for example in an essentially matrix-type arrangement enables for example a parallel analysis of a liquid to be investigated. If said liquid contains different biomolecules, for example, such as different DNA half strands, for example, and if different types of capture molecules are immobilized on the different sensor electrodes of the sensor arrangement, then the different DNA half strands can be detected temporally in parallel. In many technical fields, the parallel analysis is a desirable rationalization measure which saves operating time and thus costs. Therefore, a time-saving analysis of a liquid to be investigated is realized according to the invention.

The method according to the invention for processing a current signal provided via a sensor electrode is described in more detail below. Refinements of the circuit arrangement according to the invention, of the redox recycling sensor according to the invention and of the sensor arrangement according to the invention also apply to the method for processing a current signal provided via a sensor electrode.

The method for processing a current signal provided via a sensor electrode is effected using a circuit arrangement having the features described above.

In accordance with the method, if the current signal flowing into the control circuit via its input is outside the predetermined current intensity range, the current source is controlled by the control circuit in such a way that the current source sets the electric current generated by it in such a way that the electric current flowing into the input of the control circuit is brought to the predetermined current intensity value. By contrast, if the current signal flowing into the input of the control circuit is within the predetermined current intensity range, the control circuit controls the current source in such a way that the current source holds the electric current generated by it at the present value. Furthermore, the detection unit detects the event that the current signal flowing into the control circuit via its input is outside the predetermined current intensity range.

In accordance with an advantageous development, the number and/or the temporal sequence of the events is counted by means of a counter element that is electrically coupled to the control circuit.

In accordance with a first alternative, if the electric current flowing into the input of the control circuit exceeds an upper limit of the predetermined current intensity range, the counter reading is increased by a predetermined value. By contrast, if the electric current flowing into the input of the control circuit falls below a lower limit of the predetermined current intensity range, the counter reading is decreased by a predetermined value.

In accordance with an alternative advantageous refinement, if the electric current flowing into the input of the control circuit exceeds an upper limit of the predetermined current intensity range, the counter reading is decreased by a predetermined value, and, if the electric current flowing into the input of the control circuit falls below a lower limit of the predetermined current intensity range, the counter reading is increased by a predetermined value.

Exemplary embodiments of the invention are illustrated in the figures and are explained in more detail below.

In the figures:

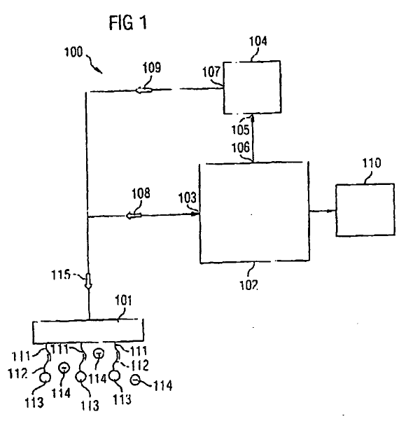

FIG. 1 shows a schematic view of a circuit arrangement in accordance with a first exemplary embodiment of the invention,

FIG. 2A shows a cross-sectional view of a sensor in accordance with the prior art in a first operating state,

FIG. 2B shows a cross-sectional view of the sensor in accordance with the prior art in a second operating state,

FIG. 3A shows a plan view of interdigital electrodes in accordance with the prior art,

FIG. 3B shows a cross-sectional view along the section line I-I′ of the interdigital electrodes in accordance with the prior art as shown in FIG. 3A,

FIG. 4A shows a biosensor based on the principle of redox recycling in a first operating state in accordance with the prior art,

FIG. 4B shows a biosensor based on the principle of redox recycling in a second operating state in accordance with the prior art,

FIG. 4C shows a biosensor based on the principle of redox recycling in a third operating state in accordance with the prior art,

FIG. 5 shows a functional profile of a sensor current in the context of a redox recycling process,

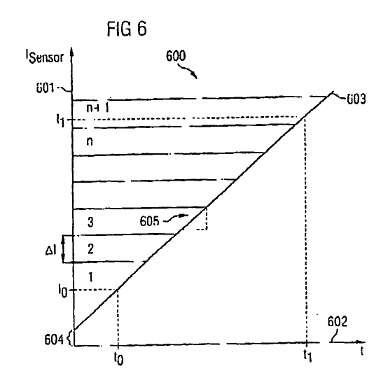

FIG. 6 shows a detailed view of the functional profile of a sensor current in the context of a redox recycling process,

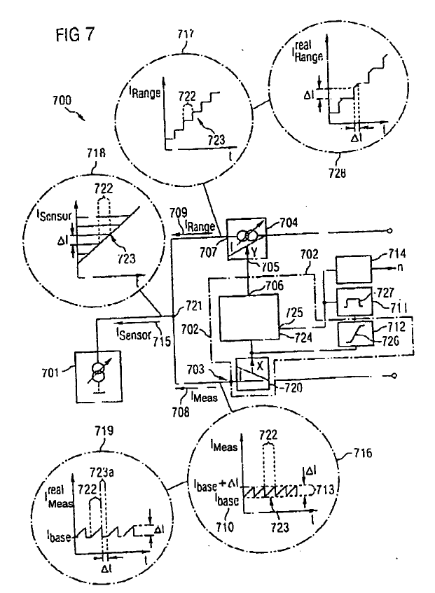

FIG. 7 shows a schematic view of a circuit arrangement in accordance with a second exemplary embodiment of the invention,

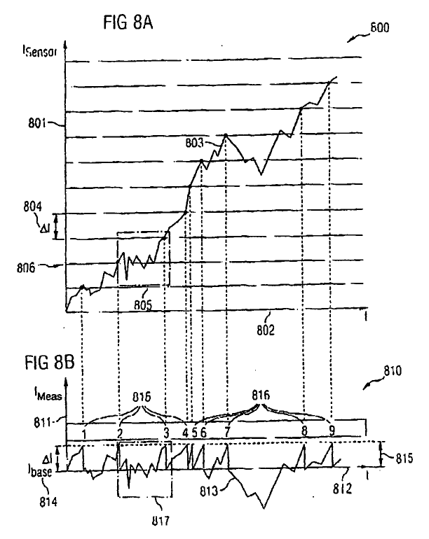

FIG. 8A shows a diagram schematically showing the dependence of the sensor current I_{Sensor} on the time t for the sensor electrode shown in FIG. 7,

FIG. 8B shows a diagram schematically showing the dependence of the measurement current I_{Meas} on the time t for the diagram illustrated in FIG. 8A,

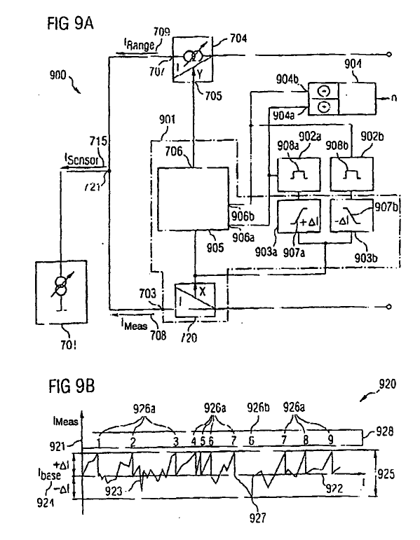

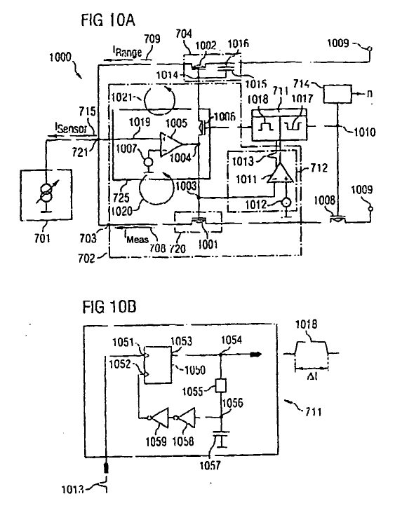

FIG. 9A shows a schematic view of a circuit arrangement in accordance with a third exemplary embodiment of the invention,

FIG. 9B shows a diagram schematically showing the dependence of the measurement current I_{Meas} on the time t for the diagram illustrated in FIG. 8A and for the third exemplary embodiment of the circuit arrangement of the invention as shown in FIG. 9A,

FIG. 10A shows a schematic view of a circuit arrangement in accordance with a fourth exemplary embodiment of the invention,

FIG. 10B shows a schematic sketch of the detection unit of the fourth exemplary embodiment of the circuit arrangement of the invention as shown in FIG. 10A.

Clearly, the invention provides inter alia an on-chip integrated circuit concept for directly converting a sensor signal of an electronic biosensor based on the principle of redox recycling into frequencies. The signal that carries this frequency is present in the form of binary signals with digital levels.

A basic idea for the invention's frequency conversion of a sensor current signal, which is realized by means of the circuit arrangement according to the invention, is shown schematically in FIG. 6 on the basis of a diagram 600.

The diagram 600 shown in FIG. 6 has an abscissa 602, along which the time t is plotted. The sensor current I_{Sensor} is plotted along the ordinate 601 of the diagram 600. Furthermore, a current-time curve profile 603 is shown. An offset current I_{Offset} 604 is furthermore entered into the diagram 600 from FIG. 6.

Proceeding from a current value I₀ at a first instant to, the current axis 601 is conceptually divided into equidistant segments of magnitude ΔI. In the time interval between the first instant t₀ and the second instant t₁, the current-time curve profile 603 sweeps over n current intervals ΔI, as shown. The invention detects in a suitable manner how many complete segments n and therefore what current interval nΔI are swept over by the sensor current I_{Sensor} in the time interval between the first instant t₀ and the second instant t₁. Referring to the nomenclature introduced above, the metrologically relevant variable is the current rise m 605, i.e. the sensor current I₁ at the second instant t₁ minus the sensor current I₀ at the first instant t₀ divided by the time interval t₁-t₀ swept over (for a current that rises linearly with time):
m=(I₁−I₀)/(t₁−t₀) (1)

On account of the subdivision of the current axis into segments ΔI and on account of the detection of the situation of a further interval ΔI respectively being exceeded, what actually is registered is, a variable m* described by the following expression:
m*(t₁)=nΔI/(t₁−t₀) (2)

For the relative error on account of the quantization of the current into current intervals ΔI of finite width, the following expression is crucial:
(m−m*)/m=1/(n+1) (3)

It can be seen from (3) that if n is chosen to be sufficiently large (i.e. if a measurement time is sufficiently long or if the current interval ΔI is chosen to be sufficiently small), the relative error can be kept comparatively small. The following holds true to an approximation for n:
n=(I₁−I₀)/ΔI (4)

Consequently, it is possible, by means of a suitable choice of the interval ΔI, to attain configurations which lead to sufficiently large values n over a dynamic range of the sensor signal, so that the residual characterization error is negligibly small.

A description is given below, with reference to FIG. 1, of a circuit arrangement 100—based on the principle described—in accordance with a first preferred exemplary embodiment of the invention.

The circuit arrangement 100 has a sensor electrode 101, a control circuit 102, which is coupled via an input 103 to the sensor electrode 101, and a current source 104, which is coupled via its control input 105 to a control output 106 of the control circuit 102 in such a way that the current source 104 can be controlled by the control circuit 102, and which is coupled via its output 107 to the sensor electrode 101. The control circuit 102 is set up in such a way that if the first current signal 108 flowing into the control circuit 102 via its input 103 is outside a predetermined current intensity range, the control circuit 102 controls the current source 104 in such a way that the current source 104 sets the second current signal 109 generated by it in such a way that the first current signal 108 flowing into the input 103 of the control circuit 102 is brought to a predetermined current intensity value. Furthermore, the control circuit 102 is set up in such a way that if the first current signal 108 flowing into the control circuit 102 via its input 103 is within the predetermined current intensity range, the control circuit 102 controls the current source 104 in such a way that the current source 104 holds the second current signal 109 generated by it at the present value. Furthermore, the circuit arrangement 100 has a detection unit 110, which can detect the event that the first current signal 108 flowing into the control circuit 102 via its input 103 is outside the predetermined current intensity range.

Furthermore, FIG. 1 shows capture molecules 111 immobilized at the sensor electrode 101. Furthermore, the illustration shows molecules 112 with an enzyme label 113 which are to be registered and have hybridized with said capture molecules 111. The system—based on the principle of redox recycling—of the sensor electrode 101, the capture molecules 111, the molecules 112 with their enzyme labels 113 which are to be registered, etc. has the effect that electrically charged particles 114 are generated, which effect a third current signal 115 of the sensor electrode 101. This third current signal 115, which corresponds to the current-time curve profile 603 illustrated in FIG. 6, contains the information of what number of particles 113 to be registered have hybridized with the capture molecules 111 on the surface of the sensor electrode 101. The circuit arrangement 100 makes it possible to filter out the sensor information from the third current signal 115.

The precise functionality of the circuit arrangement of the invention is described below with reference to FIG. 7, which shows a circuit arrangement 700 in accordance with a second exemplary embodiment of the invention.

The circuit arrangement 700 has a sensor electrode 701, a control circuit 702, which is coupled via an input 703 to the sensor electrode 701, and a current source 204, which can be controlled, via its control input 705, by the control output 706 of the control circuit 702 and is coupled via its output 707 to the sensor electrode 701. The control circuit 702 is set up in such a way that if the measurement current signal I_{Meas} 708 flowing into the control circuit 702 via its input 703 is outside a predetermined current intensity range, the control circuit 702 controls the current source 704 in such a way that the current source 704 sets the auxiliary current signal I_{Range} 709 generated by it in such a way that the measurement current signal I_{Meas} 708 flowing into the input 703 of the control circuit 702 is brought to a predetermined current intensity value I_{Base} 710. Furthermore, the control circuit 702 is set up in such a way that if the measurement current signal 708 flowing into the control circuit 702 via its input 703 is within the predetermined current intensity range, the control circuit 702 controls the current source 704 in such a way that the current source 704 holds the auxiliary current signal 709 generated by it at the present value. Furthermore, the circuit arrangement 700 has a detection unit 711, which can detect the event that the measurement current signal 708 flowing into the control circuit 702 via its input 703 is outside the predetermined current intensity range.

The predetermined current intensity range is monitored by means of a threshold value detector 712 of the control circuit 702. In accordance with the exemplary embodiment of the circuit arrangement 700 as shown in FIG. 7, the predetermined current intensity range, that is to say the range between I_{Base} and I_{Base}+ΔI, is provided with the reference numeral 713.

Furthermore, FIG. 7 shows a counter element 714 which is electrically coupled to the detection unit 711 and is set up in such a way that it counts the number and the temporal sequence of the events detected by the detection unit 711. In particular, the counter element 714 is set up in such a way that if the electric current flowing into the input 703 of the control circuit 702 exceeds the upper limit I_{Base}+ΔI, the counter reading is increased by the predetermined value “1”.

Moreover, FIG. 7 shows the sensor current signal I_{Sensor} 715 generated on account of sensor events at the sensor electrode 701.

Furthermore, FIG. 7 shows, in diagrams 716, 717, 718, the time profiles of the measurement current signal 708 (diagram 716), of the auxiliary current signal 709 (diagram 717) and of the sensor current signal 715 (diagram 718).

It must be emphasized that the diagrams 716 and 717 show an ideally desirable time dependence of the measurement current signal 708 and auxiliary current signal 709, respectively, whereas the diagrams 719 and 728 show a real time dependence of the measurement current signal 708 and auxiliary current signal 709, respectively. By means of a suitable choice of the components of the circuit arrangement 700 and of the operating method, however, it is possible to approximate the real time dependence of the measurement current signal (diagram 719) and of the auxiliary current signal 709 (diagram 717) to the ideal profile of the measurement current signal 708 (diagram 716) and auxiliary current signal 709 (diagram 717). For the purpose of a clear, simplified description of the functionality of the components of the circuit arrangement 700 a description is given below of the case where the measurement current signal 708 and the auxiliary current signal 709, respectively, can be described by means of an ideal profile as shown in diagram 716 and diagram 717, respectively.

The current source 704 shown in FIG. 7 is a voltage-controlled current source.

In the case of the circuit arrangement 700, the control circuit 702 has, at its input 703, a current-voltage converter 720 that is set up in such a way that the measurement current signal 708 present at the input 703 of the control circuit 702 is converted into an electrical voltage signal by means of the current-voltage converter 720.

The components of the circuit arrangement 700 are integrated into a silicon substrate (not shown in FIG. 7), or a portion of the components is formed on the silicon substrate.

The circuit concept shown in FIG. 7 represents a realization of the principle according to the invention. The circuit idea is based on the use of three current signals, I_{Meas} 708, I_{Range} 709 and I_{Sensor} 715, that are linked to one another via an electrical node 721.

The sensor current I_{Sensor} 715 designates the electric current that flows proceeding from the sensor electrode 701 on account of sensor events effected on the sensor electrode 701 (cf. FIG. 1). A typical time dependence of the sensor current I_{Sensor} 715 is shown in the diagram 718. The time dependence shown therein essentially corresponds to the current-time curve profile 603 described above with reference to FIG. 6. Such a curve is obtained for example in the case of a detection in accordance with the redox recycling method. The diagram 718 schematically shows that the sensor current I_{Sensor} 715 is conceptually divided into intervals ΔI.

The measurement current signal I_{Meas} 708 is characterized in that said electric current is limited to a fixed current range between I_{Base} and I_{Base}+ΔI. This current range is the predetermined current intensity range 713. If the measurement current signal I_{Meas} 708 reaches the upper threshold I_{Base}+ΔI, as shown in diagram 716, then according to the invention the auxiliary current signal I_{Range} 709 is set by means of the control circuit 702 to a current value such that the measurement current signal I_{Meas} 708 is brought back to the lower end of the current range, i.e. to the predetermined current intensity value I_{Base} 710. In other words, the auxiliary current signal I_{Range} 709 serves for limiting the measurement current signal I_{Meas} 708 to the predetermined interval 713 by taking up current components that go beyond the threshold of this channel.

In accordance with the exemplary embodiment of the circuit arrangement 700 as shown in FIG. 7, 0A is chosen as a value for the predetermined current intensity value I_{Base} 700. However, the choice of a predetermined current intensity value I_{Base} 710 that deviates from the current value 0A may be expedient in other configurations of the circuit arrangement according to the invention.

On account of the three current signals 708, 709, 715 converging at the electrical node 721, the following holds true:
I_{Sensor}=I_{Meas}+I_{Range} (5)

The functionality of the circuit arrangement 700 described below has the effect that the information relevant to the analysis of the sensor events with regard to the current rise m is contained in the measurement current signal I_{Meas 708}, whereas the auxiliary current signal I_{Range} 709 fulfils an auxiliary function.

Two operating states of the circuit arrangement 700 are explained below:

The following holds true in a first operating state (1):
I_{Meas}(t)=I_{Sensor}(t)−I_{Sensor}(t′)+I_{Base} (6a)
I_{Range}(t)=I_{Sensor}(t′)−I_{Base} (6b)

The following holds true in a second operating state (2):
I_{Meas}(t)=I_{Base} (7a)
I_{Range}(t)=I_{Sensor}(t)−I_{Base} (7b)

In this case, t designates a present instant and t′ designates a specific instant that temporally precedes the present instant t.

By way of example, a time interval that corresponds to the first operating state (1) is designated by the reference numeral 722 in the diagrams 716, 717, 718 (and also in diagram 719). In this state, the auxiliary current signal I_{Range} 709 is fixed at a constant time-independent present current value. This current value is defined by the difference between the sensor current I_{Sensor}(t′) 715 as it flowed at the previous instant t′ and by the predetermined current intensity value I_{Base} 710 (cf. (6b)). Consequently, the measurement current signal I_{Meas} 708 at the instant t is defined by the difference between the sensor current signals 715 at the instants t and t′, respectively, plus the predetermined current intensity value I_{Base} 710 (cf. (6b)). In the operating state (1), as shown in diagram 716, the measurement current signal 708 is situated within the predetermined current intensity range 713.

The operating state (2) is characterized in that the sensor current signal 715 generated at the sensor electrode 701 at the instant t, reduced by the predetermined current intensity value I_{Base} 710, forms the auxiliary current signal 709 at the instant t (cf. (7b)). Consequently, at the instant t, the measurement current signal I_{Meas} is at the predetermined current intensity value I_{Base} 710 independently of the sensor current signal I_{Sensor} 715 (cf. (7a)). The predetermined current intensity value I_{Base} 710, which as discussed above, is chosen to be 0A in accordance with the exemplary embodiment described, therefore serves for setting an operating range of the measurement current signal I_{Meas} 708. In accordance with the scenario described, wherein I_{Base}=0A is chosen, in the operating state (2), the entire sensor current signal I_{Sensor} 715 is the auxiliary current signal I_{Range} 709, so that the measurement current signal I_{Meas} 708 disappears.

The operating state (2) is identified in FIG. 7 by way of example by the instant which is designated by the reference numeral 723 and is depicted in the diagrams 716, 717, 718. Clearly, in this case, on account of the upper limit I_{Base}+ΔI being exceeded on the part of the measurement current signal I_{Meas} 708, the measurement current signal I_{Meas} 708 is reset to the predetermined current intensity value 710 and the (additional) current intensity interval ΔI is fed to the auxiliary current signal 709.

The assumption made ideally that the second operating state (2) is characterized by a shortest possible period of time, i.e. by an instant 723 in the ideal case, often cannot be achieved in reality. The temporal width Δt of a real second operating state (2) 723a is depicted in the diagram 719. However, the time interval Δt shown in the diagram 719 can be chosen in reality such that the duration of the operating state (2) is negligibly short in relation to the duration of the operating state (1). The finite duration of the second operating state (2) 723a is unimportant, however, for understanding the functionality of the circuit arrangement 700, so that it is assumed in the rest of the description that the second operating state (2) 723 can be described essentially by means of an instant.

The significance of the time interval Δt is taken up again in the generation of a detection pulse (having the temporal length Δt) described below.

The two operating states (1) and (2) 722, 723 are controlled by the control circuit 702 and the voltage-controlled current source 704 in the circuit arrangement 700.

In order to realize the operating state (2), the current source 704 is driven by the control circuit 702 by means of a parameter y, which is an electrical voltage in the case of the circuit arrangement 700. In other words, the current source 704 is a voltage-controlled current source. The measurement current signal I_{Meas 708} is transformed by means of the current-voltage converter 720 into a variable x, which is an electrical voltage in accordance with the circuit arrangement 700 described in FIG. 7. Said voltage is the output variable of the current-voltage converter 720 and the input variable of a control unit 724 of the control circuit 702. The control has the effect that the measurement current signal is at the predetermined current intensity value I_{Base}=0A 710. By means of a signal present at a further input 725 of the control unit 724, the control unit 724 is provided with the information as to whether the circuit arrangement is to be operated in the operating state (1) or in the operating state (2).

In order to be able to operate the circuit arrangement according to the invention in the operating state (1), the control unit 724 is set up in such a way that the present control value of the voltage y at a previous instant (for example t′) is held in the case of a corresponding signal at the further input 725. As soon as the auxiliary current signal I_{Range} 709 is determined by this time-independent control value, the operating state (1) is realized.

A further region of the circuit arrangement 700, namely the threshold value detector 712 of the control circuit 702, the detection unit 711 and the counter element 714 defined when the operating state (1) or (2) is realized by the circuit arrangement 700. If the input value x, which is provided to the threshold value detector 712 by means of the current-voltage converter 720 coupled thereto, exceeds the predetermined threshold value 726, then a signal is generated at the output of the threshold value detector 712 and provided to the input of the detection unit 711, which signal is such that the detection unit 711 generates a pulse 727. The pulse 727 generated by the detection unit 711 is provided to the further input 725 of the control unit 724. This pulse provided to the control unit 724 informs the control unit 724 of the fact that the predetermined threshold value 726 has been exceeded at the threshold value detector 712, which is the case if the measurement current signal I_{Meas} 708 exceeds the value I_{Base}+ΔI. The exceeding of the threshold value 726 is equivalent to the event that the measurement current signal I_{Meas} 708 has exceeded the predetermined current intensity range 713, i.e. has exceeded the current intensity value I_{Base}+ΔI.

It must be emphasized that the temporal length of the pulse 727 of the detection unit 711 corresponds to that length which, in the diagram 719, is designated by Δt as the real length of the second operating state 723a.

It may be expedient for the pulse 727 generated by the detection unit 711 to have a shortest possible temporal length Δt→0.

The pulse 727 provided at the further input of the control unit 724 has the effect that, during the time duration Δt of the pulse 727, the control unit 724 controls the circuit arrangement 700 in such a way that the second operating state (t) is maintained during this time interval Δt. In the absence of such a pulse 727 at the further input 725 of the control unit 724, the circuit arrangement 700 is in the operating state (1).

The result of the interplay of all the circuit components of the circuit arrangement 700 is illustrated in the diagrams 716, 717, 718. If the measurement current signal I_{Meas} 708 exceeds the value I_{Base}+ΔI, then the measurement current signal I_{Meas} is reset to the predetermined current intensity value I_{Base} 710 with the aid of the operating state (2). After resetting, the measurement current signal I_{Meas} 708 once again rises with a rate determined by the sensor current signal I_{Sensor} 715. The pulses 727 generated by the detection unit 711 during each reset process are provided not only to the further input 725 of the control unit 724 but also, as shown in FIG. 7, to the counter element 714. The counter element 714 counts the number of pulses and the temporal sequence thereof. In other words, the counter element 714 registers the number n of pulses in digital form, and it is thereby possible to determine at the counter element 714 what current intensity increase nΔI has taken place in the measurement time period registered.

In order that said number n is identical to the number of times the sensor current signal I_{Sensor} 715 is exceeded over ΔI segments within the time period t₀-t₁, the magnitude Δt should preferably be negligibly short in relation to the time between two reset processes. Under this precondition, which can often be fulfilled well in practice, it is possible to determine the current rise m* over n. If n is chosen to be sufficiently large or ΔI sufficiently small or the measurement time sufficiently long, then m may be assumed to be as an approximation equal to m*.

It must be emphasized that the described method for processing a sensor current signal 715 provided via a sensor electrode 701 can be employed even when the time interval Δt, i.e. the length of the pulse 727, is not negligibly short. In such a scenario, the variable m* that is to be registered metrologically can be determined in accordance with the following expression:
m*(t₁)=nΔI/(t₁−t₀−nΔt) (8)

It must be emphasized that, in a departure from the circuit arrangement 700 shown in FIG. 7, instead of providing the counter element 714, it is also possible directly to register the frequency of the pulses 727 at the output of the detection unit 711. This frequency contains the information of the sensor current signal I_{Sensor} 715.

The method for processing a sensor current signal I_{Sensor} 715 provided via the sensor electrode 701, which method is based on the use of the circuit arrangement 700, has the following steps in summary: if the measurement current signal I_{Meas} 708 flowing into the control circuit 702 via its input 703 is outside the predetermined current intensity range 713, the control circuit 702 controls the current source 704 in such a way that the current source 704 sets the electrical auxiliary current signal I_{Range} 709 generated by it in such a way that the electric measurement current signal I_{Meas} 708 flowing into the input 703 of the control circuit 702 is brought to the predetermined current intensity value I_{Base} 710. If the measurement current signal I_{Meas} 708 flowing into the control circuit 702 via its input 703 is within the predetermined current intensity range 713, the control circuit 702 controls the current source 704 in such a way that the current source 704 holds the electric auxiliary current signal I_{Range} 709 generated by it at the present value.

Furthermore, the detection unit 711 detects the event that the measurement current signal I_{Meas} 708 flowing into the control circuit 702 via its input 703 is outside the predetermined current intensity range 713.

A description is given below, with reference to figure BA, FIG. 8B, of how the principle according to the invention functions if the sensor current signal I_{Sensor} deviates from its ideal linear form (cf. FIG. 6) and signal fluctuations (for example on account of noise effects) occur.

FIG. 8A shows a diagram 800, along the abscissa of which the time t 802 is plotted, and along the ordinate of which the electric sensor current 801 is plotted. As shown in FIG. 8A, the sensor current-time curve profile 803 is not linear, but rather has fluctuations.

FIG. 8B shows a further diagram 810, along the abscissa of which the time t 812 is plotted, which corresponds to the time 802 plotted in figure BA. The electric measurement current 811 is plotted along the ordinate of the further diagram 810. Furthermore,

FIG. 8B plots the measurement current-time curve profile 813 as results during the operation of the circuit arrangement 700 according to the invention for the case where the sensor current-time curve profile 803 illustrated in FIG. 8A is present.

Furthermore, FIG. 8A shows a current intensity interval ΔI 804. The predetermined current intensity range essential for the functionality of the circuit arrangement according to the invention, that is to say the range between a predetermined current intensity value I_{Base} 814 and I_{Base}+ΔI, is designated by the reference numeral 815 in FIG. 8B.

After each further occasion that the electric sensor current I_{Sensor} exceeds a current intensity interval ΔI 804, the electric measurement current 811 is reset. These reset points 816 are shown in FIG. 8B, and their number corresponds to the characteristic variable n introduced above. What is crucial for the functionality of the circuit arrangement for indirectly registering the electric sensor current 801 is that when a specific current interval line is repeatedly exceeded, precisely one reset and thus counting process is initiated. This phenomenon can be comprehended if a measurement interval of the sensor current 805 is compared with a measurement interval of the measurement current 817. Within the time period defined by the measurement intervals 805, 817, the current interval line 806 shown in FIG. 8A is multiply exceeded and undershot in the measurement interval of the sensor current 805 (for example on account of noise effects or the like). FIG. 8B reveals, however, that in the measurement interval of the measurement current 817, a reset point 816 can be seen only on the first occasion when the current interval line 806 is exceeded. In other words, a pulse that is counted by a counter element is output only upon the first occasion when a current interval line 806 is exceeded. All further occasions when the same current interval line 806 is exceeded no longer reach the threshold value I_{Base}+ΔI in FIG. 8B.

The method for processing a current signal provided via a sensor electrode, which method is based on the circuit arrangement according to the invention, is thus robust with respect to signal fluctuations. The averaging effect achieved by means of the method is furthermore advantageous in the determination of the current curve rise.

The measurement current-time curve profile 813 shown in FIG. 8B shows that the electric measurement current 811 is upwardly limited on account of the progressive resetting when the current value I_{Base}+ΔI is exceeded. However, a lower limitation of the current is not given.

FIG. 9A shows a circuit arrangement 900 in accordance with a third exemplary embodiment of the invention, which represents a development of the circuit arrangement 700 shown in FIG. 7. Those elements of the circuit arrangement 900 from FIG. 9A which are identical to components of the circuit arrangement 700 are provided with the same reference symbols in FIG. 9A and are not explained in any more detail below.

The circuit arrangement 900 shown in FIG. 9A has the advantageous development in comparison with the circuit arrangement 700 shown in FIG. 7 that the electric measurement current is also downwardly limited.

In contrast to the circuit arrangement 700 shown in FIG. 7, the circuit arrangement 900 has the following components: a control circuit 901, the control unit 905 of which has a first further input 906a and a second further input 906b instead of the further input 725 from FIG. 7. The detection unit of the circuit arrangement 900 shown in FIG. 9A has a first region of the detection unit 902a and a second region of the detection unit 902b. The threshold value detector of the circuit arrangement 900 has a first region of the threshold value detector 903a and a second region of the threshold value detector 903b. The voltage signal x provided by the current-voltage converter 720 at the output thereof is provided to the control unit 905 and both to the first region of the threshold value detector 903a and to the second region of the threshold value detector 903b.

The first region of the threshold value detector 903a essentially fulfils the same functionality as the threshold value detector 712 shown in FIG. 7. If the voltage signal x provided to the input of the first region of the threshold value detector 903a by the current-voltage converter 720 exceeds a first predetermined threshold value 907a of the first region of the threshold value detector 903a, then a corresponding signal is communicated from the output of the first region of the threshold value detector 903a to the input of the first region of the detection unit 902a, said input being coupled to said output. The first region of the detection unit 902a has an output that is coupled to the first further input 906a of the control unit 905 and that is coupled to the first input 904a of the counter element 904. The first region of the detection unit 902a generates a first pulse 908a, which is provided to the first further input 906a of the control unit 905 and which is provided to the first input 904a of the counter element 904. The first pulse signal 908a has the effect, at the first further input 906a of the control unit 905, that the measurement current signal I_{Meas} 708 is reset from the value I_{Base}+ΔI to the value I_{Base}. The first pulse 908a has the effect, at the first input 904a of the counter element 904, that the counter reading of the counter element 904 is increased by a predetermined value (for example by “1”). In this respect, the functionality of the circuit arrangement 900 corresponds to that of the circuit arrangement 700.

Furthermore, the voltage signal x that is generated by the current-voltage converter 720 and is characteristic of the present measurement current signal 708 is provided to the second region of the threshold value detector 903b at the input thereof. If the voltage signal x falls below the second predetermined threshold value 907b of the second region of the threshold value detector 903b, then a corresponding electric signal is generated at the output of the second region of the threshold value detector 903b, which is coupled to the input of the second region of the detection unit 902b, and said electric signal is communicated to the input of the second region of the detection unit 902b. In this case, a second pulse 908b is generated by the second region of the detection unit 902b. The output of the second region of the detection unit 902b is coupled both to the second further input 906b of the control unit 905 and to the second input 904b of the counter element 904. Therefore, if the second pulse 908b is generated at the second region of the detection unit 902b, said second pulse is provided to these two inputs. The scenario described corresponds to the scenario that is designated by the instant 927 in FIG. 9b and in the case of which the measurement current signal 708 reaches the lower limit I_{Base}−ΔI of the predetermined current intensity range 925. The second pulse signal 908b provided to the control unit 905 at the second further input 906b thereof effects control of the current source 704 in such a way that the measurement signal I_{Meas} 708 is reset to the predetermined current intensity value I_{Base} 924. The second pulse 908b provided to the second input 904b of the counter element 904 has the effect there that the counter reading of the counter element 904b is decreased by a predetermined value (for example by “1”). A correct summation of the reset pulses is thereby realized, since the reset pulse effected at the instant 927 is not caused by an increase in the sensor current by a further current intensity range 804, but rather a decrease in the current signal that can be attributed for example to noise effects.

In other words, the circuit arrangement 900 from FIG. 9A realizes a limitation of the measurement current signal I_{Meas} to the predetermined current intensity range 925 between I_{Base}−ΔI and I_{Base}+ΔI. The circuit arrangement shown in FIG. 9A thus represents an advantageous development of the circuit arrangement 700, since a lowering of the measurement current signal 708 can also be detected correctly by means of the circuit arrangement 900. The counter element 904 of the circuit arrangement 900 is designed as an up/down counter.

The functionality of the circuit arrangement 900 from FIG. 9A is described below with reference to the diagram 920 from FIG. 9B.

The diagram 920 has an abscissa, along which the time 922 is plotted. The electric measurement current 921 is plotted along the ordinate. Furthermore, the diagram shows the measurement current-time curve profile 923 as is obtained using the circuit arrangement 900 shown in FIG. 9A in the case of a sensor current-time curve profile 803 as is shown in FIG. 8A. The electric measurement current 921 remains within the predetermined current intensity range 925 around the predetermined current intensity value I_{Base} 924 with a bandwidth ΔI extending upward and downward. FIG. 9b furthermore shows first reset points 926a and a second reset point 926b. A comparison of the measurement current time curve profile 923 with the sensor current-time curve profile 803 shows that the first reset points reflect a respective increase in the sensor current 801 by a further current intensity interval 804, whereas the reset point 926b symbolizes the decrease—which can be recorded at the instant 927—in the sensor current 801 by a current intensity interval ΔI 804. The second pulses 908b generated by the “+ΔI” event are fed to the up input 904a of the counter element 904, and the second pulses 908b generated by the “−ΔI” event are fed to the down input 904b of the counter element 904. Consequently, the counter reading 928 increases by the predetermined value of “1” in the case of each first reset point 926a, whereas the counter, reading 928 decreases by “1” in the case of the second reset point 926b. The circuit arrangement 900 shown in FIG. 9A consequently enables a completely correct summation of the pulses even in a scenario in which the sensor current decreases occasionally on account of undesirable effects.

A detailed description is given below, with reference to FIG. 10A, FIG. 10B, of a fourth preferred exemplary embodiment of a circuit arrangement 1000 according to the invention.

The circuit arrangement 1000 shown in FIG. 10A represents a circuitry realization of the circuit arrangement 700 shown in FIG. 7. Therefore, those circuit blocks of the circuit arrangement 1000 which are configured as an equivalent element in the circuit arrangement 700 are provided with the same reference numerals.

The sensor electrode 701, proceeding from which the sensor current signal 715 flows, is coupled to one source-drain region of a first p-MOS transistor 1001, which forms the current-voltage converter 720. Furthermore, the electrical node 721 is coupled to one source-drain region of a second p-MOS transistor 1002. The measurement current signal I_{Meas} 708 flows between the electrical node 721 and the first p-MOS transistor 1001, and the auxiliary current signal I_{Range} flows between the node 721 and one source-drain region of the second p-MOS transistor 1002. The gate region of the first p-MOS transistor 1001 is coupled to a second electrical node 1003. The second electrical node 1003 is coupled to a third electrical node 1004. The third electrical node 1004 is coupled to the output of a first operational amplifier 1005. Furthermore, the third electrical node 1004 is coupled to one source-drain region of a third p-MOS transistor 1006. The noninverted input of the first operational amplifier 1005 is coupled to the electrical node 721. The noninverted input of the first operational amplifier 1005 is coupled to a first reference voltage source 1007. The other source-drain region of the first p-MOS transistor 1001 is coupled to one source-drain region of a fourth p-MOS transistor 1008. The other source-drain region of the fourth p-MOS transistor 1008 is coupled to a supply voltage source 1009. The gate region of the fourth p-MOS transistor 1008 is coupled to a fourth electrical node 1010. The fourth electrical node 1010 is coupled to the output of the detection unit 711 and to the input of the counter element 714. The second electrical node 1003 is furthermore coupled to the inverted input of a second operational amplifier 1011. The noninverted input of the second operational amplifier 1011 is coupled to a second reference voltage source 1012. The output of the second operational amplifier 1011, at which a first output signal 1013 may be present, is coupled to the input of the detection unit 711. A further output of the detection unit 711 is coupled to the gate region of the third p-MOS transistor 1006. The other source-drain region of the third p-MOS transistor 1006 is coupled to a fifth electrical node 1014. The fifth electrical node 1014 is coupled to the gate region of the second p-MOS transistor 1002 and to a storage capacitor 1015. The storage capacitor 1015 is furthermore coupled to a sixth electrical node 1016. The sixth electrical node 1016 is furthermore coupled to the other source-drain region of the second p-MOS transistor 2002. The sixth electrical node 1016 is furthermore coupled to the supply voltage source 1009.

The second p-MOS transistor 1002 and the storage capacitor 1015 connected in parallel therewith form the voltage-controlled current source 704. The first reference voltage source 1007, the first operational amplifier 1005, the third electrical node 1004 and the third p-MOS transistor 1006 form the control unit 725.

The second operational amplifier 1011 and the second reference voltage source 1012 form the threshold value detector 712. As indicated in FIG. 10A, the detection unit 711 is set up in such a way that, in a scenario in which a first output signal 1013 is provided to the input of the detection unit 711 by the threshold value detector 712, the detection unit 711 provides a first pulse 1017 to the counter element 714 and to the gate region of the fourth p-MOS transistor 1008. Furthermore, the detection unit 711 is designed in such a way that, in a scenario in which a first output signal 1013 is provided to the detection unit 711 by the threshold value detector 712, the detection unit 711 provides a second pulse 1018 to the gate region of the third p-MOS transistor 1006.

The precise configuration of the counter 714 is not shown in FIG. 10A. The counter 714 may be for example a synchronous binary counter constructed from JK flip-flops.

The precise construction of the detection unit 711 is explained in detail below with reference to FIG. 10B.

It should be pointed out that the circuit arrangement 1000 shown in FIG. 10A, in contrast to the circuit arrangement 700 shown in FIG. 7, has an electrical coupling means 1019 for coupling the electrical node 721 to the control unit 725, more precisely to the noninverted input of the first operational amplifier 1005 of the control unit 725. In order to achieve the function of the electrical node 721 as a summation point in accordance with equation (5), it is to be ensured that the current disappears in this additional line which is formed by means of the electrical coupling means 1019. This requirement is fulfilled well if the transistors of the input differential stage of the first operational amplifier 1005 are designed as MOS transistors.

Two different active control loops 1020, 1021 result in a manner dependent on the conduction state of the third and fourth p-MOS transistors 1006, 1008.

The output of the first operational amplifier 1005 is fed back to the noninverted input in inverting fashion by means of the second or first p-MOS transistor 1002, 1001, respectively. The open-loop gain of the first operational amplifier 1005 is designated by A1 hereinafter. The following then holds true as long as the feedback ensures that the first operational amplifier 1005 does not enter into limitation:
V_{Out}=A1(V_{K}−V_{Bias}) (9)

V_{Out} is the voltage present at the output of the first operational amplifier 1005. V_{K} is the voltage present at the electrical node 721 and therefore at the noninverted input of the first operational amplifier 1005, and V_{Bias} is the electrical voltage provided to the inverted input of the first operational amplifier by the first reference voltage source 1007. The following then results after simple transformation:
V_{K}=V_{Bias}+V_{Out}/A1 (10)

For a large open-loop gain (A1→∞), it then follows from equation (10) that the voltage present at the electrical node 721 is equal to the electrical voltage provided at the inverted input of the first operational amplifier 1005 by the first reference voltage source 1007.

The potential at the electrical node 721 is thus adjusted to the value V_{Bias} prescribed by the first reference voltage source 1007 at the inverted input of the first operational amplifier 1005. This voltage value, which simultaneously determines the electrical potential at the sensor electrode 701, is necessary in order to enable the redox recycling process.

The first control state 1020 and the second control state 1021 are described in more detail below.

Firstly a description is given of the first control loop 1020 which corresponds to the operating state of the circuit arrangement according to the invention that is designated above by operating state (1).

This case corresponds to the scenario wherein the detection unit 711 does not generate a first pulse 1017 and a second pulse 1018 at its output and at its further output. The lack of provision of a first pulse 1017, which, in accordance with FIG. 10A, represents a logic value “0” in a departure from a logic value “1” that otherwise prevails in constant fashion, means that the gate region of the fourth p-MOS transistor 1008 is conducting. Since the detection unit 711 does not generate a second pulse 1018, which, as shown in FIG. 10A, would generate the logic value “1” proceeding from a logic value “0” for the duration of the pulse, the gate region of the third p-MOS transistor 1006 is not conducting. In accordance with the first control state 1020, the gate region of the third p-MOS transistor 1006 is thus nonconducting, whereas the gate region of the fourth p-MOS transistor 1008 is conducting.

Since the gate region of the third p-MOS transistor 1006 is not conducting, a constant electrical voltage is present at the storage capacitor 1015 and thus at the gate region of the second p-MOS transistor 1002. Since a constant electrical voltage is likewise present at the electrical node 721, a time-independent auxiliary current I_{Range} 709 results through the gate region of the second p-MOS transistor 1002. The temporally changed sensor current I_{Sensor} 715 therefore flows through the gate region of the first p-MOS transistor 1001. The electrical voltage at the output of the first operational amplifier 1005 is established such that the electrical voltage at the gate region of the first p-MOS transistor 1001 enables the required current flow.

A description is given below of the second control loop 1021, which corresponds to the operating state of the circuit arrangement 1000 that is designated as operating state (2) above. In accordance with this scenario, the detection unit 711, on account of a corresponding first output signal 1013 at its input, generates a first pulse 1017 and a second pulse 1018 at its two outputs. The first pulse 1018, as shown in FIG. 10A, is set up in such a way that the gate region of the third p-MOS transistor 1006 thereby becomes conducting. By contrast, the first pulse 1017, as shown in FIG. 10A, is set up in such a way that, during the pulse duration, the gate region of the fourth p-MOS transistor 1008 becomes nonconducting. Since the gate region of the fourth p-MOS transistor 1008 is nonconducting, a vanishing measurement current I_{Meas} 7008 (I_{Meas}=0) results independently of the output voltage of the first operational amplifier 1005. By contrast, the gate region of the third p-MOS transistor 1006 is in the conducting state, and, in accordance with this scenario, the output voltage of the first operational amplifier 1005 is the gate voltage of the second p-MOS transistor 1002, and therefore controls the auxiliary current I_{Range} that flows through the gate region of the second p-MOS transistor 1002. The gate voltage of the second p-MOS transistor 1002 is controlled by the circuit arrangement 1000 in such a way that the auxiliary current I_{Range} 709 is equal to the sensor current I_{Sensor} 715. The entire sensor current of the sensor electrode 701 is thus conducted away into the range channel.

A changeover in the operating state of the circuit arrangement 1000 from the second operating state 1021 to the first operating state 1020 therefore corresponds to a change in the conduction state of the third and fourth p-MOS transistors 1006, 1008 proceeding from a state in which the third p-MOS transistor 1006 is conducting and the fourth p-MOS transistor 1008 is nonconducting, through to a state in which the third p-MOS transistor 1006 is nonconducting and the fourth p-MOS transistor 1008 is conducting.

If the third p-MOS transistor 1006 is switched such that it is nonconducting, by means of the electrical voltage at the storage capacitor 1015, the auxiliary current I_{Range} 709 is stored by means of the second p-MOS transistor 1002. Therefore, in the first operating state 1020, the measurement current I_{Meas} 708 is the sensor current I_{Sensor} 715 minus the stored auxiliary current I_{Range} 709.

The third and fourth p-MOS transistors 1006, 1008 are driven by means of the second pulse 1018 and the first pulse 1017 of the detection unit 711. In the first operating state 1020 of the circuit arrangement 1000, an increase in the sensor current I_{Sensor} 715 leads to a larger measurement current I_{Meas} 708. The gate voltage of the first p-MOS transistor 1001 decreases correspondingly. If the gate voltage falls below the value of the voltage of the second reference voltage source 1012 of the second operational amplifier 1011, then a positive edge is generated at the output of the second operational amplifier 1011 (which functions as a comparator). Said edge excites the detection unit 711 to generate a pulse. As already discussed above, the detection unit is set up in such a way that, in the normal state, the two outputs of the detection unit 711 switch the operating state (1) 1020. In other words, the gate region of the third p-MOS transistor 1006 is nonconducting, whereas the gate region of the fourth p-MOS transistor 1008 is conducting. A first pulse 1017 and a second pulse 1018 are generated in the detection unit 711 and produce the second operating state (2) for a predetermined time interval Δt. In accordance with this scenario, the gate region of the third p-MOS transistor 1006 is conducting, whereas the gate region of the fourth p-MOS transistor 1008 is nonconducting. In this second operating state, the measurement current I_{Meas} 708 is returned to the value 0, and at the same time a new auxiliary current I_{Range} 709 is defined. The number of reset processes is realized by registering the number of pulses by means of the counter element 714, the number and the temporal sequence of the pulses being stored digitally in the counter element 714.

An exemplary embodiment of the detection unit 711 according to the invention is described below with reference to FIG. 10B.

The exemplary embodiment of the detection unit 711 as described in FIG. 10B shows how, proceeding from the first output signal 1013 of the threshold value detector 712, it is possible to generate a pulse having the temporal length Δt, which provides a signal having a logic value “1” for a time period Δt, whereas the signal assumes a logic value “0” before the pulse and after the pulse. Such a pulse corresponds to the pulse 1018 shown in FIG. 10A. A first pulse 1017 from FIG. 10A may be generated for example by firstly generating a pulse of the type of the second pulse 1018 and subtracting this pulse from a constant signal.

The detection unit 711 shown in FIG. 10B has a flip-flop 1050 having a first input 1051, a second input 1052 and an output 1053. The first input 1051 is the edge-sensitive input of the flip-flop 1050, and the first output signal 1013 defined and shown in FIG. 10A is applied to said input. As a result, the output 1053 of the flip-flop 1050 is brought from a logic value “0” to a logic value “1”. The output 1053 of the flip-flop 1050 is coupled to an electrical node 1054. Said electrical node is coupled to a nonreactive resistor 1055. The nonreactive resistor 1055 is coupled to a second electrical node 1056. The second electrical node 1056 is coupled to a capacitor 1057. Furthermore, the second electrical node 1056 is coupled to a first amplifier stage 1058, and the first amplifier stage 1058 is coupled to a second amplifier stage 1059. The second amplifier stage 1059 is coupled to the second input 1052 of the flip-flop 1050. The functionality of the amplifier stages 1058, 1059 is to be seen in the fact that defined logic levels are present at the second input 1052 of the flip-flop 1050. The output edge at the output 1053 of the flip-flop 1050 is delayed by means of the RC element formed from the nonreactive resistor 1056 and the capacitor 1057 and is used as a reset for the flip-flop 1050. What is generated as a result is a pulse having the length Δt proportional to RC, where R is the resistance of the nonreactive resistor 1055 and C is the capacitance of the capacitor 1057. Therefore, the pulse duration is essentially determined by an RC element.

The following publications are cited in this document:
[1] Hintsche, R, Paeschke, M, Uhlig, A, Seitz, R (1997) “Microbiosensors using Electrodes made in Si-technoloty”, Frontiers in Biosensorics, Fundamental Aspects, Scheller, F W, Schuber L, F, Fedrowitz, J (eds.), Birkhauser Verlag Basle, Switzerland, pp. 267-283
[2] van Gerwen, P (1997) “Nanoscaled interdigitated Electrode Arrays for Biochemical Sensors”, IEEE, International Conference on Solid-State Sensors and Actuators, Jun. 16-19, 1997, Chicago, pp. 907-910
[3] Paeschke, M, Dietrich, F, Uhlig, A, Hintsche, R (1996) “Voltammetric Multichannel Measurements Using Silicon Fabricated Microelectrode Arrays”, Electroanalysis, Vol. 7, No. 1, pp. 1-8
[4] Uster, M, Loeliger, T. Guggenbühl, W, Jäckel, H (1999) “Integrating ADC Using a Single Transistor as Integrator and Amplifier for Very Low (1fA Minimum) Input Currents”, Advanced A/D and D/A Conversion Techniques and Their Applications, Strathclyde University Conference (Great Britain) Jul. 27-28, 1999, Conference Publication No. 466, pp. 06-89, IEE

### List of Reference Symbols

100 Circuit arrangement
101 Sensor electrode
102 Control circuit
103 Input
104 Current source
105 Control input
106 Control output
107 Output
108 First current signal
109 Second current signal
110 Detection unit
111 Capture molecules
112 Molecules to be registered
113 Enzymes
114 Electrically charged particles
115 Third current signal
200 Sensor
201 Electrode
202 Electrode
203 Insulator
204 Electrode terminal
205 Electrode terminal
206 DNA probe molecule
207 Electrolyte
208 DNA strands
300 Interdigital electrode
400 Biosensor
401 First electrode
402 Second electrode
403 Insulator layer
404 Holding region of first electrode
405 DNA probe molecule
406 Electrolyte
407 DNA strand
408 Enzyme
409 Cleavable molecule
410 Negatively charged first partial molecule
411 Arrow
412 Further solution
413 Oxidized first partial molecule
414 Reduced first partial molecule
500 Diagram
501 Electric current
502 Time
503 Current-time curve profile
504 Offset current
600 Diagram
601 Electric sensor current
602 Time
603 Current-time curve profile
604 Offset current
605 Gradient of the current-time curve profile
700 Circuit arrangement
701 Sensor electrode
702 Control circuit
703 Input
704 Current source
705 Control input
706 Control output
707 Output
708 Measurement current signal
709 Auxiliary current signal
710 Predetermined current intensity value
711 Detection unit
712 Threshold value detector
713 Predetermined current intensity range
714 Counter element
715 Sensor current signal
716 Diagram
717 Diagram
718 Diagram
719 Diagram
720 Current-voltage converter
721 Electrical node
722 First operating state
723 Second operating state
723a Real second operating state
724 Control unit
725 Further input
726 Predetermined threshold value
727 Pulse
728 Diagram
800 Diagram
801 Electric sensor current
802 Time
803 Sensor current-time curve profile
804 Current intensity interval
805 Measurement interval of the sensor current
806 Current interval line
810 Diagram
811 Electric measurement current
812 Time
813 Measurement current-time curve profile
814 Predetermined current intensity value
815 Predetermined current intensity range
816 Reset points
817 Measurement interval of the measurement current
900 Circuit arrangement
901 Control circuit
902a First region of the detection unit
902b Second region of the detection unit
903a First region of the threshold value detector
903b Second region of the threshold value detector
904 Counter element
904a First input
904b Second input
905 Control unit
906a First further input
906b Second further input
907a First predetermined threshold value
907b Second predetermined threshold value
908a First pulse
908b Second pulse
920 Diagram
921 Electric measurement current
922 Time
923 Measurement current-time curve profile
924 Predetermined current intensity value
925 Predetermined current intensity range
926a First reset points
926b Second reset point
927 Instant
928 Counter reading
1000 Circuit arrangement
1001 First p-MOS transistor
1002 Second p-MOS transistor
1003 Second electrical node
1004 Third electrical node
1005 First operational amplifier
1006 Third p-MOS transistor
1007 First reference voltage source
1008 Fourth p-MOS transistor
1009 Supply voltage source
1010 Fourth electrical node
1011 Second operational amplifier
1012 Second reference voltage source
1013 First output signal
1014 Fifth electrical node
1015 Storage capacitor
1016 Sixth electrical node
1017 First pulse
1018 Second pulse
1019 Electrical coupling means
1020 First control loop
1021 Second control loop
1050 Flip-flop
1051 First input
1052 Second input
1053 Output
1054 Electrical node
1055 Nonreactive resistor
1056 Second electrical node
1057 Capacitor
1058 First inverter stage
1059 Second inverter stage

1-17. (canceled)

18. A circuit arrangement comprising:
a sensor electrode;
a control circuit coupled to the sensor electrode via an input;
a current source having a control input which is coupled to a control output of the control circuit in such a way that the current source can be controlled by the control circuit, and which is coupled to the sensor electrode via an output;
the control circuit arranged in such a way that if a current signal provided to the input of the control circuit
is outside a predetermined current intensity range, the control circuit controls the current source in such a way that the current source sets the electric current generated by it in such a way that the electric current flowing into the input of the control circuit is brought to a predetermined current intensity value;
is within the predetermined current intensity range, the control circuit controls the current source in such a way that the current source holds the electric current generated by it at the present value; and
a detection unit, which can detect the event that the current signal flowing into the control circuit via its input is outside the predetermined current intensity range.

19. The circuit arrangement of claim 18, further comprising
a counter element electrically coupled to the detection unit and which is set up in such a way that it counts a number or a temporal sequence of the events detected by the detection unit.

20. The circuit arrangement of claim 19, wherein the counter element is set up in such a way that if the current signal provided to the input of the control circuit exceeds an upper limit of the predetermined current intensity range, the counter reading is increased by a predetermined value.

21. The circuit arrangement of claim 20 wherein the counter element is set up in such a way that if the current signal provided to the input of the control circuit falls below a lower limit of the predetermined current intensity range, the counter reading is decreased by a predetermined value.

22. The circuit arrangement of claim 19, wherein the counter element is set up in such a way that if the current signal provided to the input of the control circuit exceeds an upper limit of the predetermined current intensity range, the counter reading is decreased by a predetermined value.

23. The circuit arrangement of claim 22, wherein the counter element is set up in such a way that if the current signal provided to the input of the control circuit falls below a lower limit of the predetermined current intensity range, the counter reading is increased by a predetermined value.

24. The circuit arrangement of claim 18 in which the current source is a voltage-controlled current source.

25. The circuit arrangement of claim 18 wherein the control circuit comprises:
a current-voltage converter at its input set up in such a way that the current present at the input of the control circuit is converted into an electrical voltage signal by means

26. The circuit arrangement of claim 18 wherein the sensor electrode, the control circuit, the current source and the detection unit are combined in a common integrated circuit.

27. A redox recycling sensor comprising the circuit arrangement of claims 18.

28. A method for processing a current signal the method comprising:
detecting a current signal at an input of a control circuit;
generating an electric current at a current source;
if the current signal at the input of the control circuit
is outside the predetermined current intensity range, the control circuit controls the current source in such a way that the current source sets the electric current generated by it in such a way that the current detected at the input of the control circuit is brought to a predetermined current intensity value;
is within the predetermined current intensity range, the control circuit controls the current source in such a way that the current source holds the electric current generated by it at a present value;
detecting as an event the current signal being outside the predetermined current intensity range flowing into input of the control circuit.

29. The method of claim 28 further comprising:
counting in a counter a number or a temporal sequence of the events.

30. The method of claim 29 further comprising:
if the current signal detected at the input of the control circuit exceeds an upper limit of the predetermined current intensity range, increasing the counter by a predetermined value.

31. The method of claim 30 further comprising:
if the current signal detected at the input of the control circuit falls below a lower limit of the predetermined current intensity range, decreasing the counter by a predetermined value.

32. The method as claimed in claim 29 further comprising:
if the current signal detected at the input of the control circuit exceeds an upper limit of the predetermined current intensity range, decreasing the counter by a predetermined value.

33. The method as claimed in claim 32 further comprising:
if the current signal detected at the input of the control circuit falls below a lower limit of the predetermined current intensity range, increasing the counter by a predetermined value.

34. A circuit arrangement for a redox recycling sensor comprising:
a sensor electrode configured to sense hybridization of a DNA strand with an enzyme label at a capture molecule immolized on the sensor electrode, the enzyme generating free charge carriers that bring about a current flow at the sensor electrode when a correspondingly suitable liquid is added;
a control circuit having an input coupled to the sensor electrode for detecting the current flow at the sensor electrode as a measured current;
a current source having a control input which is coupled to a control output of the control circuit in such a way that the current source can be controlled by the control circuit, and which is coupled to the sensor electrode via an output;
the control circuit arranged in such a way that if the measured current
is outside a predetermined current intensity range, the control circuit controls the current source in such a way that the current source sets a range current generated by it in such a way that the measured current detected at the input of the control circuit is brought to a predetermined current intensity value;
is within the predetermined current intensity range, the control circuit controls the current source in such a way that the current source holds the range current generated by it at the present value; and
a detection unit, which can detect the event that the measured current at the control circuit input is outside the predetermined current intensity range.
